(19) United States
(12) Patent Application Publication
(10) Pub. No.: US 2016/0329312 A1
(43) Pub. Date: Nov. 10, 2016

(54) SEMICONDUCTOR CHIP WITH OFFLOADED LOGIC

(71) Applicants: Sean M. O'Mullan, Austin, TX (US); Michael S. Alfano, Austin, TX (US); Bryan Black, Austin, TX (US)

(72) Inventors: Sean M. O'Mullan, Austin, TX (US); Michael S. Alfano, Austin, TX (US); Bryan Black, Austin, TX (US)

(21) Appl. No.: 14/704,044

(22) Filed: May 5, 2015

(51) Int. Cl. H01L 25/18; G01R 31/28; H01L 23/498; H01L 21/66; H01L 25/00

(52) U.S. Cl. CPC H01L 25/18; H01L 22/34; H01L 25/50; H01L 23/49838; G01R 31/2884; G01R 31/2834

(57) ABSTRACT

Various semiconductor chip and interposer devices are disclosed. In one aspect, an apparatus is provided that includes an interposer, a first semiconductor chip mounted on the interposer and a second semiconductor chip mounted on and electrically connected to the first semiconductor chip by the interposer. The second semiconductor chip includes offloaded logic of the first semiconductor chip.

### BACKGROUND OF THE INVENTION

1. Field of the Invention

This invention relates generally to semiconductor processing, and more particularly to interposer based semiconductor chips and methods of using the same.

2. Description of the Related Art

Conventional microprocessor data paths typically consist of logic units to facilitate the movement and other processing of data. Conventional data paths are typically designed using a single process technology node. The newest generations of processors normally use the most current, and thus smallest geometry, process node to construct data path logic. While this can yield better performance, cutting edge process nodes can tend to have lower yields and higher costs.

Design-for-Test (DFT) circuits are used to perform in-house testing various of aspects of conventional processors. Conventional DFT circuits are currently designed to be implemented directly into the microprocessor silicon. As such, they consume die area, consume power and dissipate heat. However, these DFT circuits are seldom used by the end user. Since DFT circuit design must compete with other logic for die space, conventional DFT circuits often compromise performance to accommodate operational die logic.

Automated test equipment (ATE) systems are used to test modern processors. The ATE runs test vectors (scripts) through the processor undergoing test. On conventional ATE test systems, the amount of test vectors that can be used is constrained by the size of the memory of the ATE test system.

The present invention is directed to overcoming or reducing the effects of one or more of the foregoing disadvantages.

### SUMMARY OF THE INVENTION

In accordance with one aspect of the present invention, an apparatus is provided that includes an interposer, a first semiconductor chip mounted on the interposer and a second semiconductor chip mounted on and electrically connected to the first semiconductor chip by the interposer. The second semiconductor chip includes offloaded logic of the first semiconductor chip.

In accordance with another aspect of the present invention, a method of manufacturing is provided that includes providing a first semiconductor chip and a second semiconductor chip. The second semiconductor chip includes offloaded logic of the first semiconductor chip. The first semiconductor chip is then electrically connected to the second semiconductor chip.

In accordance with another aspect of the present invention, a method of manufacturing is provided that includes fabricating a first semiconductor chip and a second semiconductor chip. The second semiconductor chip includes offloaded logic of the first semiconductor chip.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of an interposer that is shown exploded from an exemplary circuit board;

FIG. 2 is a sectional view of FIG. 1 taken at section 2-2;

FIG. 3 is a schematic view of the interposer depicted in FIG. 1;

FIG. 4 is a pictorial view of an alternate exemplary embodiment of an interposer;

FIG. 5 is a schematic view of the interposer depicted in FIG. 4;

FIG. 6 is a pictorial view of multiple exemplary semiconductor chips mounted on a circuit board; and

FIG. 7 is a pictorial view of an exemplary interposer exploded from an exemplary electronic device.

### DETAILED DESCRIPTION OF SPECIFIC EMBODIMENTS

Various multi-semiconductor chip arrangements are disclosed. The disclosed embodiments take logic from one semiconductor chip and offload it to another semiconductor chip. The two chips are then electrically connected by an interposer. The first semiconductor chip can be wholly or partly fabricated at the most current process node, while the offloaded logic in the second semiconductor chip may be fabricated at an earlier process node where yields may be higher and costs lower. In this way, logic such as data path or DFT circuits can be offloaded and can function using the high speed pathways of the interposer. Additional details will now be disclosed.

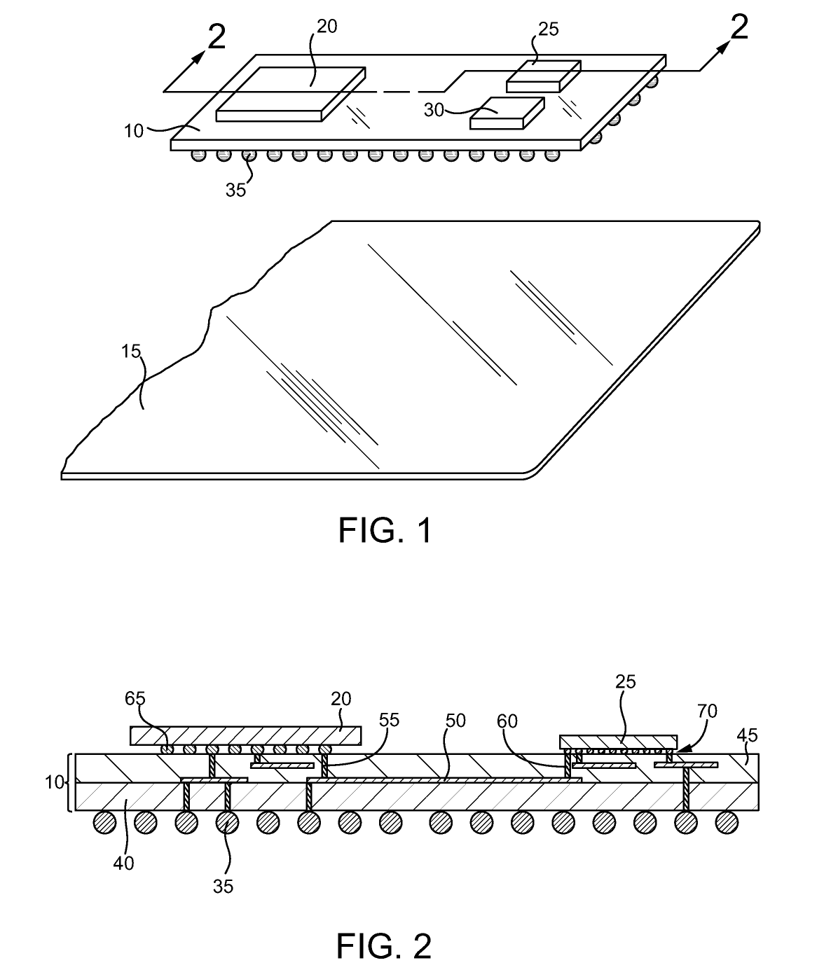

In the drawings described below, reference numerals are generally repeated where identical elements appear in more than one figure. Turning now to the drawings, and in particular to FIG. 1, therein is shown a pictorial view of an exemplary embodiment of an interposer 10 that is shown exploded from an exemplary circuit board 15. The interposer 10 may be populated with one or more semiconductor chips, three of which are depicted and labeled 20, 25 and 30 respectively. The depicted arrangement uses 2D stacking, but 3D stacking may be used in addition to or in lieu of 2D. The interposer 10 may be composed of a variety of materials suitable for use in a stacked semiconductor chip arrangement. Some desirable properties include, for example, a coefficient of thermal expansion that is relatively close to the coefficients of thermal expansion of the semiconductor chips 20, 25 and 30, ease of manufacture, and thermal conductivity. Exemplary materials include, for example, silicon, germanium, sapphire, diamond, carbon nanotubes in a polymer matrix, or the like. Here, the interposer 10 and the circuit board 15 have rectangular footprints. However, the interposer 10 and the circuit board 15 may be fabricated with virtually any type of footprint.

The semiconductor chips 20, 25 and 30 may be any of a myriad of different types of circuit devices used in electronics. Examples include, for example, integrated circuits dedicated to video processing, central processing units (CPU), graphics processing units (GPU), accelerated processing units (APU) that combines microprocessor and graphics processor functions, a system-on-chip, application specific integrated circuits, memory devices, active optical devices, such as lasers, passive optical devices or the like. These examples may be single or multi-core or even stacked laterally with additional dice. The semiconductor chips 20, 25 and 30 may be constructed of bulk semiconductor, such as silicon or germanium, or semiconductor on insulator materials, such as silicon-on-insulator materials, or other chip or even insulating materials. The semiconductor chips 20, 25 and 30 may be bare semiconductor substrates or packaged parts mounted on the interposer 10. If packaged parts, a great variety of variations may be used, such as flip chip BGA packages, chip scale packages, glob top, lidded packages, pin grid arrays, lead frame devices or virtually any other type of semiconductor chip package.

The circuit board 15 may be a package substrate, a motherboard, a circuit card, or virtually any other type of printed circuit board. Although a monolithic structure could be used for the circuit board 15, a more typical configuration will utilize a buildup design. In this regard, the circuit board 15 may consist of a central core upon which one or more buildup layers are formed and below which an additional one or more buildup layers are formed. The core itself may consist of a stack of one or more layers. If implemented as a package substrate, the number of layers in the circuit board 15 can vary from four to sixteen or more, although less than four may be used. So-called “coreless” designs may be used as well. The layers of the circuit board 15 may consist of an insulating material, such as various well-known epoxies, interspersed with metal interconnects. A multi-layer configuration other than buildup could be used. Optionally, the circuit board 15 may be composed of well-known ceramics, single or multi-layer, or other materials suitable for package substrates or other printed circuit boards. The circuit board 15 is provided with a number of conductor traces and vias and other structures (not visible) in order to provide power, ground and signals transfers between the semiconductor chips 20, 25 and 30 and the interposer 10 and another device, such as another circuit board (not shown) for example. To interface the semiconductor chips 20, 25 and 30 with the circuit board 15, the interposer 10 may be provided with plural I/Os 35, which in this illustrative embodiment may be solder balls 35 of a ball grid array. Optionally, the I/Os 35 may be conductive pillars, solder joints or other types of interconnects. The circuit board 15 may also be provided with multiple I/Os (not shown) to facilitate electrical thereof to another device(s). Examples include ball grid arrays, pin grid arrays, land grid arrays or other types of I/Os.

Additional details of the interposer 10 may be understood by referring now to FIG. 2, which is a sectional view of the interposer 10 in FIG. 1 taken at section 2-2. Note section 2-2 uses an offset cutting plane such that the interposer 10, the semiconductor chip 20, and the semiconductor chip 25 will be shown in section but the semiconductor chip 30 depicted in FIG. 1 will not be visible. The interposer 10 may be fabricated with a semiconductor substrate 40 and an interconnect stack 45. The semiconductor substrate 40 may be composed of the interposer materials disclosed supra. The interconnect stack 45 may consist of plural interconnect layers that are either formed en masse on the substrate 40 or sequentially as a series of build-up interlevel dielectric and metallization layers. The interconnect stack 45 may include numerous examples of conductor traces and vias. In this regard, one of the traces connecting the semiconductor chip 20 to the semiconductor chip 25 is labeled 50. Conductive vias that link the semiconductor chips 20 and 25 to the trace 50 are labeled 55 and 60, respectively. Depending upon the complexity of the interposer 10, there may be one, two, three or even more layers that make up the interconnect stack 45. In this illustrative embodiment, the semiconductor chip 20 may be mounted and connected electrically to the interposer 10 by way of plural interconnect structures 65, which may be solder bumps, gold bumps, conductive pillars or other types of interconnect structures. The semiconductor chip 25 may be similarly connected to the interposer 10 electrically and physically by way of plural interconnect structures 70 which may be like the interconnect structure 65, albeit with sizes scaled as appropriate to the footprint of the semiconductor chip 25 relative to the semiconductor chip 20. As noted above, the exemplary BGA 35 is used to electrically and physically mount the interposer 10 to the circuit board 15 depicted in FIG. 1.

Any of the conductor structures disclosed herein as possibly being composed of solder may be composed of various types of solders, such as lead-free or lead-based solders. Examples of suitable lead-free solders include tin-silver (about 97.3% Sn 2.7% Ag), tin-copper (about 99% Sn 1% Cu), tin-silver-copper (about 96.5% Sn 3% Ag 0.5% Cu) or the like. Examples of lead-based solders include tin-lead solders at or near eutectic proportions or the like. The traces 50 and vias may be composed of copper, aluminum, gold, silver, palladium, platinum or other conductors.

As noted above, the semiconductor chips 20, 25 and 30 may be any of a great variety of different types of devices. However, in this illustrative embodiment the semiconductor chip 20 may be a processor and the semiconductor chip 25 may be an integrated circuit that includes logic that would, in a conventional design, be implemented in the semiconductor chip 20. This logic is offloaded from the semiconductor chip 20 and implemented in the semiconductor chip 25 with the interposer 10 serving as a high speed, high bandwidth bus between the two. The offloaded logic can take a variety of forms. A non-exhaustive list includes data path logic, design-for-test (DFT) circuits or other logic. A data path is a collection of functional units, such as but not limited to arithmetic logic units, multipliers, fetch and decoders, data storage, and I/O units that perform data processing or data movement operations. The data path and a control unit(s) are central parts of many processor designs (CPU, GPUs, APUs, MPUs). The control unit(s) largely regulates interaction between the data path and the data itself, which is usually stored in registers or main memory. The semiconductor chip 30 depicted in FIG. 1 may also be used to offload logic. At the design stage for the semiconductor chip 20 and the semiconductor chip 25 (and/or the semiconductor chip 30), logic of the semiconductor chip 20, for example an arithmetic logic unit or a DFT, is selected to be offloaded to the semiconductor chip 25. That logic is then eliminated from the design and manufacture of the semiconductor chip 20 but incorporated into the design and manufacture of the semiconductor chip 25.

The circuitry of the semiconductor chip 20 and the semiconductor chip 25 and/or the semiconductor chip 30 may be at the same process node or at different process nodes. As noted briefly above, the semiconductor chips 25 and 30 or at least the offloaded processor logic portions thereof may be advantageously fabricated at a less advanced, and thus larger geometry, process node than the circuits of the semiconductor chip 20. This has several important advantages. Typically, leading edge process nodes have lower yields and higher costs. Moving logic, such as portions of the data path and/or DFT circuits, to the semiconductor chip 25 and/or the semiconductor chip 30 built with older process nodes can save overall cost. Moving logic in the form of DFT circuits can provide multiple benefits. Most DFT circuits are not needed after manufacturing testing. Offloading them to the semiconductor chip 25 and/or the semiconductor chip 30 can shrink the die size of the semiconductor chip 20, reduce the power consumption of the semiconductor chip 20 (since they are off-chip and can be powered down). Offloaded DFT circuitry can be larger and more liberally designed since the packing constraints of the semiconductor chip 20 are not a consideration, and run on voltage supplies separate from the voltage supply of the semiconductor chip 20. This increases the stability of the DFT logic and provides for greater testing voltage range for the semiconductor chip 20. Finally, offloaded DFT logic can be manufactured with onboard memory, typically non-volatile. The onboard memory can be used to store test vectors (scripts) to be run on and test the semiconductor chip 20. This may supplement what may be memory constraints associated with available ATE used to test the semiconductor chip 20. A non-exhaustive list of DFT circuits includes memory built-in self test circuits, high speed I/O loopback or test circuits or smaller/cheaper processors or microcontrollers, which can exercise the semiconductor chip 20 in a functional manner.

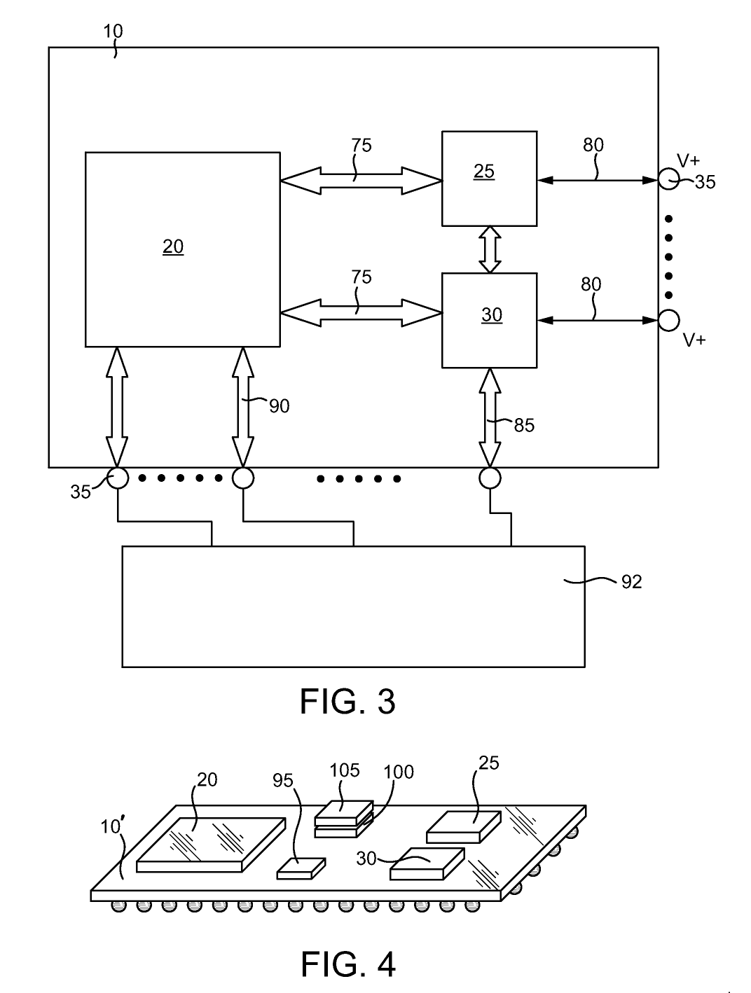

Additional details of the interposer 10 may be understood by referring now also to FIG. 3, which is a schematic view. Signals 75 may be routed between the semiconductor chip 20 and the semiconductor chips 25 and 30 by way of the interposer 10. If need be, power 80 may be supplied to the semiconductor chips 25 and 30 by way of the I/Os 35 that are connected to a power rail or other type of power supply. Note that the ellipses denote variable numbers of I/Os 35. Optionally, signals 85 may be routed to and from one or more of the semiconductor chips 25 and 30 by way of one or more of the I/Os 35. Signals 90 may be routed to and from the semiconductor chip 20 by way of additional I/Os 35 of the interposer 10 (any disclosed alternatives), and from there to an ATE 92, which may be any type of automated test equipment.

As just noted, one or more of the semiconductor chips 25 or 30 may be directly tied to one or more of the I/Os 35 of the interposer 10. This may be used to directly connect the semiconductor chips 25 and 30 to the ATE 92 that is coupled to the interposer 10. Of course the test signals may be routed from the interposer 10 to the semiconductor chip 20 and ultimately to the semiconductor chips 25 and 30 and thus there would be no need to route the signals 85 directly through one or more of the I/Os 35. During testing of the interposer 10 and the semiconductor chip 20, the semiconductor chips 25 and 30, if implemented as DFT components, may be used to test the semiconductor chip 20. Following testing and during actual field usage, the semiconductor chips 25 and 30 may be powered down to save overall system power. Test vectors may be run from the ATE 92, the semiconductor chip 25 and/or the semiconductor chip 30 or both.

An alternate exemplary embodiment of an interposer 10′ may be understood by referring now to FIG. 4, which is a pictorial view. Here, the interposer 10′ may be populated with the semiconductor chip 20, the semiconductor chips 25 and 30, and additional components, which may be for example additional semiconductor chips 95, 100 and 105. The semiconductor chips 95, 100 and 105 may be any of a huge variety of different types of integrated circuits, such as memory devices, communications chips, etc. Here, the semiconductor chips 25 and 30 may serve the functions described above and in addition may be used to provide interposer based testing devices for the additional functional devices 95, 100 and 105. It may even be possible, as with the semiconductor chip 20, to off load some of the data path logic from the devices 95, 100 and 105 on to the semiconductor chips 25 and 30, again using perhaps less advanced process node technology for the semiconductor chips 25 and 30 as described above in conjunction with the semiconductor chip 20. Note that the embodiment in FIG. 4 incorporates both 2D and 3D stacking concepts.

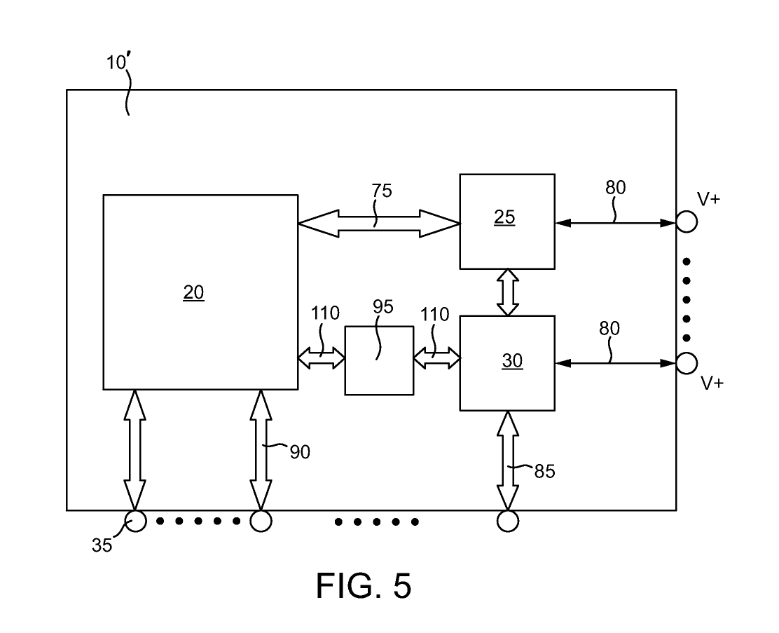

The alternate exemplary interposer 10′ depicted in FIG. 4 is depicted schematically in FIG. 5. For simplicity of illustration, the semiconductor chip 20, the semiconductor chips 25 and 30 are depicted but only the semiconductor chip 95 of the additional functional devices is depicted. As described above, signals 75 between the semiconductor chip 20 and the semiconductor chips 25 and 30 may be routed through the interposer 10′. The same is true with regard to power 80, optional signals 85 and signals 90 as described above in conjunction with FIG. 3. Here, signals 110 to and from the device 95 may be routed by way of the interposer 10′. The signals may be between the device 95 and the semiconductor chips 25 and 30 and/or between the semiconductor chip 20 and the device 95. The I/Os 35 function as described above.

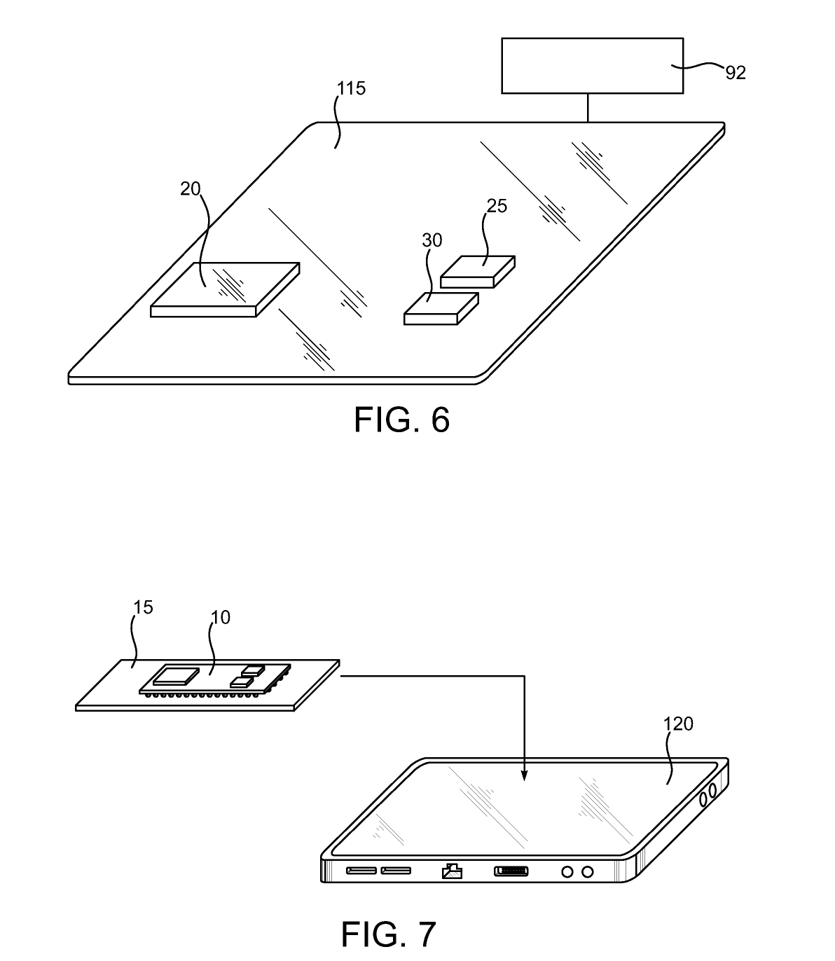

In still another alternate exemplary embodiment depicted pictorially in FIG. 6, the semiconductor chip 20 may be temporarily mounted to a circuit board 115, which may be a multi-level organic or multi-level ceramic type of circuit board configured as a test fixture. The semiconductor chips 25 and 30 or their logical equivalents may be mounted on or otherwise incorporated into the circuit board 115. Once mounted, the semiconductor chip 20 may be subjected to testing using the logic of the semiconductor chips 25 and 30 and the ATE 92. Thereafter, the semiconductor chip 20 may be removed from the circuit board 115 and thereafter mounted on another circuit board or if not already on an interposer then on, for example, any of the disclosed interposers 10, 10′ etc.

As depicted in FIG. 7, the interposer 10 and any disclosed alternatives may be mounted to the circuit board 15 and the combination in turn mounted on or in an electronic device 120, which may be a personal computer, a server, a hand held device such as a smart phone or tablet computer or other computing device. As part of the computing device 120, the interposer 10 may be used to perform computing operations.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

1. An apparatus, comprising:
an interposer;
a first semiconductor chip mounted on the interposer; and
a second semiconductor chip mounted on, and electrically connected to the first semiconductor chip by the interposer, the second semiconductor chip including offloaded logic of the first semiconductor chip.

2. The apparatus of claim 1, wherein the offloaded logic comprises a part of a data path of the first semiconductor chip.

3. The apparatus of claim 1, wherein the offloaded logic comprises a DFT circuit operable to test an aspect of the first semiconductor chip.

4. The apparatus of claim 1, comprising a third semiconductor chip mounted on the interposer.

5. The apparatus of claim 1, comprising an ATE connected to the interposer.

6. The apparatus of claim 1, comprising an electronic device, the interposer being mounted on or in the electronic device.

7. The apparatus of claim 1, wherein the first semiconductor chip comprises circuits of a first process node and the offloaded logic comprises circuits of a second process node of larger geometry than the first process node.

8. A method of manufacturing, comprising:
providing a first semiconductor chip;
providing a second semiconductor chip, the second semiconductor chip including offloaded logic of the first semiconductor chip; and
electrically connecting the first semiconductor chip to the second semiconductor chip.

9. The method of claim 8, comprising mounting the first semiconductor chip and the second semiconductor chip to an interposer, the interposer electrically connecting the first semiconductor chip to the second semiconductor chip.

10. The method of claim 9, comprising a third semiconductor chip mounted on the interposer.

11. The method of claim 8, wherein the offloaded logic comprises a part of a data path of the first semiconductor chip.

12. The method of claim 8, wherein the offloaded logic comprises a DFT circuit operable to test an aspect of the first semiconductor chip.

13. The method of claim 8, comprising connecting the first semiconductor chip to an ATE.

14. The method of claim 8, comprising mounting the first semiconductor chip and the second semiconductor chip on or in an electronic device.

15. A method of manufacturing, comprising:
fabricating a first semiconductor chip; and
fabricating a second semiconductor chip, the second semiconductor chip including offloaded logic of the first semiconductor chip.

16. The method of claim 15, comprising electrically connecting the first semiconductor chip and the second semiconductor chip.

17. The method of claim 16, comprising mounting the first semiconductor chip and the second semiconductor chip on an interposer, the interposer electrically connecting the first semiconductor chip to the second semiconductor chip.

18. The method of claim 15, wherein the offloaded logic comprises a part of a data path of the first semiconductor chip.

19. The method of claim 15, wherein the offloaded logic comprises a DFT circuit operable to test an aspect of the first semiconductor chip.

20. The method of claim 15, comprising connecting the first semiconductor chip to an ATE.

21. The method of claim 15, comprising mounting the first semiconductor chip and the second semiconductor chip on or in an electronic device.
